(19) United States
(12) Patent Application Publication
(10) Pub. No.: US 2022/0231142 A1
(43) Pub. Date: Jul. 21, 2022

(54) SILICON CARBIDE SEMICONDUCTOR DEVICE AND MANUFACTURING METHOD THEREOF

(71) Applicant: SUMITOMO ELECTRIC INDUSTRIES, LTD., Osaka (JP)

(72) Inventor: Kotaro TANAKA, Osaka (JP)

(21) Appl. No.: 17/595,864

(22) PCT Filed: Aug. 3, 2020
(86) PCT No.: PCT/JP2020/029621

§ 371 Date: Nov. 29, 2021

(30) Foreign Application Priority Data
Aug. 5, 2019 (JP) 2019-143976

(51) Int. Cl. H01L 29/423; H01L 29/16; H01L 29/78; H01L 29/66; H01L 29/40; H01L 29/04

(52) U.S. Cl. CPC H01L 29/42376; H01L 29/1608; H01L 29/4236; H01L 29/045; H01L 29/66068; H01L 29/401; H01L 29/7813

(57) ABSTRACT

A silicon carbide semiconductor device includes a silicon carbide substrate having a first principal surface provided with a gate trench, and a second principal surface located on an opposite side from the first principal surface, the gate trench having an inner surface connecting to the first principal surface, a gate insulator provided on the inner surface of the gate trench, and a gate electrode provided on the gate insulator, wherein the gate electrode includes a base portion in contact with the gate insulator, and filling a portion of the gate trench, and a tapered portion provided on the base portion, having a width which continuously decreases in a direction further away from the base portion, in a cross sectional view viewed from a direction perpendicular to a longitudinal direction of the gate trench, and wherein a boundary between the base portion and the tapered portion is located at a position closer to a bottom of the gate trench than an upper end of the gate trench.

### TECHNICAL FIELD

The present disclosure relates to silicon carbide semiconductor devices, and manufacturing methods thereof.

This application is based upon and claims priority to Japanese Patent Application No. 2019-143976 filed on Aug. 5, 2019, the entire contents of which are incorporated herein by reference.

### BACKGROUND ART

A known silicon carbide semiconductor device includes a trench formed in one principal surface of a silicon carbide substrate, a gate electrode provided so as to extend from inside the trench to above the principal surface, and a gate insulator provided between the silicon carbide substrate and the gate electrode (for example, Patent Document 1).

### PRIOR ART DOCUMENTS

### Patent Documents

Patent Document 1: Japanese Laid-Open Patent Publication No. 2019-96794

### DISCLOSURE OF THE INVENTION

A silicon carbide semiconductor device according to the present disclosure includes a silicon carbide substrate having a first principal surface provided with a gate trench, and a second principal surface located on an opposite side from the first principal surface, the gate trench having an inner surface connecting to the first principal surface; a gate insulator provided on the inner surface of the gate trench; and a gate electrode provided on the gate insulator, wherein the gate electrode includes a base portion in contact with the gate insulator, and filling a portion of the gate trench, and a tapered portion provided on the base portion, having a width which continuously decreases in a direction further away from the base portion, in a cross sectional view viewed from a direction perpendicular to a longitudinal direction of the gate trench, and wherein a boundary between the base portion and the tapered portion is located at a position closer to a bottom of the gate trench than an upper end of the gate trench.

### BRIEF DESCRIPTION OF DRAWINGS

FIG. 1 is a cross sectional view illustrating a structure of a silicon carbide semiconductor device according to a first embodiment.

FIG. 2 is a cross sectional view (part 1) illustrating a method of manufacturing the silicon carbide semiconductor device according to the first embodiment.

FIG. 3 is a cross sectional view (part 2) illustrating the method of manufacturing the silicon carbide semiconductor device according to the first embodiment.

FIG. 4 is a cross sectional view (part 3) illustrating the method of manufacturing the silicon carbide semiconductor device according to the first embodiment.

FIG. 5 is a cross sectional view (part 4) illustrating the method of manufacturing the silicon carbide semiconductor device according to the first embodiment.

FIG. 6 is a cross sectional view (part 5) illustrating the method of manufacturing the silicon carbide semiconductor device according to the first embodiment.

FIG. 7 is a cross sectional view (part 6) illustrating the method of manufacturing the silicon carbide semiconductor device according to the first embodiment.

FIG. 8 is a cross sectional view illustrating the structure of the silicon carbide semiconductor device according to a modification of the first embodiment.

### MODE OF CARRYING OUT THE INVENTION

### Problem to be Solved by the Present Disclosure

In conventional silicon carbide semiconductor devices, it is difficult to sufficiently cope with the recent demands to further improve the high withstand voltage.

Accordingly, it is one object of the present disclosure to provide a silicon carbide semiconductor device and a manufacturing method thereof, which can improve the withstand voltage of a gate insulator.

### Effects of the Present Disclosure

According to the present disclosure, it is possible to improve the withstand voltage of the gate insulator.

Embodiments for carrying out the present disclosure will be described below.

### Description of Embodiments of the Present Disclosure

First, embodiments of the present disclosure will be described with reference to examples. In the following description, the same or corresponding elements are designated by the same reference numerals, and a description of the same or corresponding elements will not be repeated. In crystallographic representations used in this specification, individual crystal planes are represented by ( ), and crystal lattice planes are represented by { }, respectively. In addition, a negative index according to the crystallographic representation is generally represented by adding a “−(bar)” above the numeral, however, this specification represents the negative index by adding a negative sign in front the numeral.

[1] A silicon carbide semiconductor device according to one aspect of the present disclosure includes a silicon carbide substrate having a first principal surface provided with a gate trench, and a second principal surface located on an opposite side from the first principal surface, the gate trench having an inner surface connecting to the first principal surface; a gate insulator provided on the inner surface of the gate trench; and a gate electrode provided on the gate insulator, wherein the gate electrode includes a base portion in contact with the gate insulator, and filling a portion of the gate trench, and a tapered portion provided on the base portion, having a width which continuously decreases in a direction further away from the base portion, in a cross sectional view viewed from a direction perpendicular to a longitudinal direction of the gate trench, and wherein a boundary between the base portion and the tapered portion is located at a position closer to a bottom of the gate trench than an upper end of the gate trench.

The present inventor, as a result of diligent studies, found that an alignment error of the gate electrode is one cause of insulation breakdown of the gate insulator, and a distance between a side surface of the gate electrode and the upper end of the gate trench may become smaller than a designed value. In the conventional silicon carbide semiconductor device, because a width of the gate electrode is a maximum at a portion of the gate electrode making contact with the gate insulator, the electric field tends to concentrate at a lower end of the side surface of the gate electrode. For this reason, if the distance between the side surface of the gate electrode and the upper end of the gate trench becomes smaller than the designed value, an excessive electric field is applied to the gate insulator between the gate electrode and a vicinity of a corner portion at the upper end of the gate trench, and a sufficiently high withstand voltage may not be obtainable. On the other hand, in a case where the tapered portion is included in the gate electrode, the width of the tapered portion continues to become narrower as the distance from the base portion increases, the distance between the gate electrode and the vicinity of the corner portion at the upper end of the gate trench becomes greater than a thickness of the gate insulator, thereby relaxing the electric field. Accordingly, even if an alignment error occurs during the manufacturing process, the insulation breakdown is reduced by relaxing the concentration of the electric field, thereby enabling the withstand voltage of the gate insulator to be improved.

[2] In [1], a side surface of the tapered portion may be a curved surface having a concave shape which curves inward toward the tapered portion. The curved surface having the concave shape can easily be formed by isotropic etching.

[3] In [1] or [2], a width of an upper end of the tapered portion may be in a range greater than or equal to 80% and less than or equal to 95% of an opening width at the upper end of the gate trench. When the width is in a range greater than or equal to 90% and less than or equal to 95% of the opening width, it is possible to obtain an excellent withstand voltage using a simple process.

[4] In any one of [1] to [3], the silicon carbide substrate may include a first impurity layer having a first conductivity type, a second impurity layer, provided on a surface of the first impurity layer closer to the first principal surface, and having a second conductivity type different from the first conductivity type, and a third impurity layer, provided on a surface of the second impurity layer closer to the first principal surface so as to be separated from the first impurity layer, and having the first conductivity type, and the inner surface of the gate trench may reach the first impurity layer by penetrating the third impurity layer and the second impurity layer.

[5] In [4], a lower end of the tapered portion may be separated from an interface between the second impurity layer and the third impurity layer toward the upper end of the gate trench by a distance which is greater than or equal to 80% of a thickness of the third impurity layer. When the lower end of the tapered portion is separated by the distance which is greater than or equal to 80% of the thickness of the third impurity layer, it is possible to reduce the insulation breakdown of the gate insulator caused by a surge un the electric field between the second impurity region and the gate electrode.

[6] In any one of [1] to [5], the base portion may oppose the second impurity layer via the gate insulator interposed therebetween.

[7] In any one of [1] to [6], the gate trench may include a trench sidewall having a (0-33-8) plane. When the gate trench includes the trench sidewall having the (0-33-8) plane, it is possible to obtain excellent mobility at the side surface of the gate trench, and reduce a channel resistance.

[8] A silicon carbide semiconductor device according to one aspect of the present disclosure includes a silicon carbide substrate having a first principal surface provided with a gate trench, and a second principal surface located on an opposite side from the first principal surface, wherein the silicon carbide substrate includes a first impurity layer having a first conductivity type, a second impurity layer, provided on a surface of the first impurity layer closer to the first principal surface, and having a second conductivity type different from the first conductivity type, and a third impurity layer, provided on a surface of the second impurity layer closer to the first principal surface so as to be separated from the first impurity layer, and having the first conductivity type, wherein the gate trench has an inner surface, connecting to the first principal surface, and reaching the first impurity layer by penetrating the third impurity layer and the second impurity layer; a gate insulator provided on the inner surface of the gate trench; and a gate electrode provided on the gate insulator, wherein the gate electrode includes a base portion in contact with the gate insulator, filling a portion of the gate trench, and opposing the second impurity layer via the gate insulator interposed therebetween, and a tapered portion provided on the base portion, having a width which continuously decreases in a direction further away from the base portion, in a cross sectional view viewed from a direction perpendicular to a longitudinal direction of the gate trench, wherein a boundary between the base portion and the tapered portion is located at a position closer to a bottom of the gate trench than an upper end of the gate trench, and wherein a side surface of the tapered portion is a curved surface having a concave shape which curves inward toward the tapered portion.

[9] A manufacturing method of a silicon carbide semiconductor device according to one aspect of the present disclosure includes the steps of preparing a silicon carbide substrate having a principal surface; forming, in the principal surface, a gate trench having an inner surface connecting to the principal surface; forming a gate insulator on the inner surface of the gate trench; forming a quasi-gate electrode on the gate insulator, filling a portion of the gate trench, and extending upward from an upper end of the gate trench; and forming a gate electrode by etching the quasi-gate electrode, wherein the gate electrode after the etching includes a base portion in contact with the gate insulator, and filling a portion of the gate trench, and a tapered portion provided on the base portion, having a width which continuously decreases in a direction further away from the base portion, in a cross sectional view viewed from a direction perpendicular to a longitudinal direction of the gate trench.

The gate electrode having the tapered portion with the width which continuously decreases in the direction further away from the base portion is famed by etching the quasi-gate electrode. For this reason, the distance between the gate electrode and the vicinity of the corner portion at the upper end of the gate trench becomes greater than the thickness of the gate insulator, thereby relaxing the electric field. Accordingly, even if an alignment error occurs during the manufacturing process, the insulation breakdown is reduced by relaxing the concentration of the electric field, thereby enabling the withstand voltage of the gate insulator to be improved.

### Details of Embodiments of the Present Disclosure

Although one embodiment of the present disclosure will now be described in detail, the present disclosure is not limited thereto.

### First Embodiment

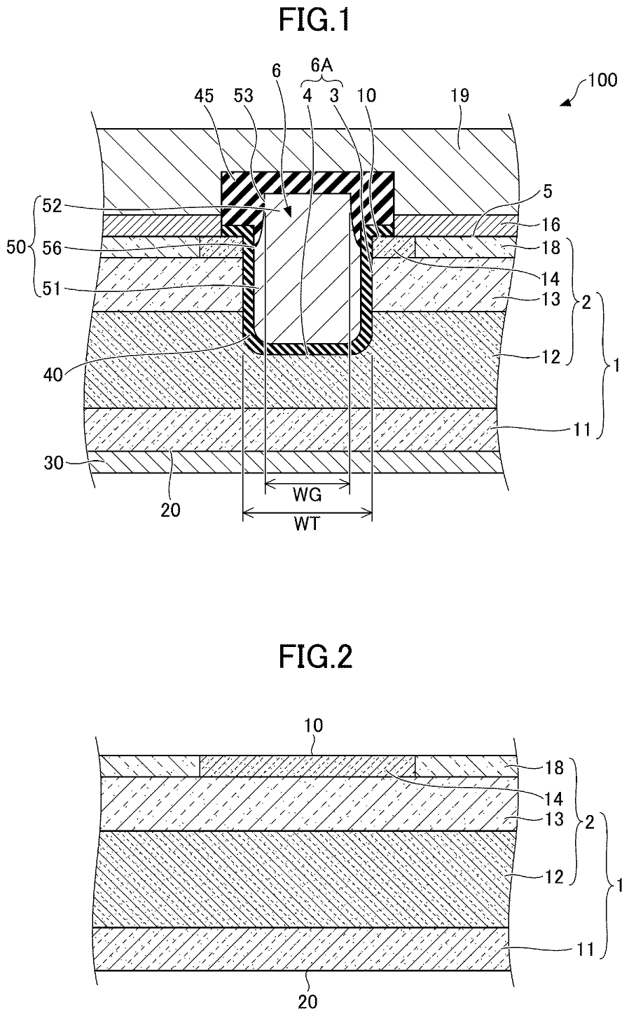

First, a description will be given of a first embodiment of the present disclosure. The first embodiment relates to a so-called vertical silicon carbide semiconductor device. FIG. 1 is a cross sectional view illustrating a structure of the silicon carbide semiconductor device according to the first embodiment.

As illustrated in FIG. 1, a silicon carbide semiconductor device 100 according to the first embodiment generally has a silicon carbide substrate 1, a source electrode 16, a drain electrode 30, a source interconnect 19, a gate insulator 40, a gate electrode 50, and an interlayer insulator 45. The silicon carbide substrate 1 includes a silicon carbide single crystal substrate 11, and a silicon carbide epitaxial layer 2. The silicon carbide epitaxial layer 2 is provided on the silicon carbide single crystal substrate 11. The silicon carbide substrate 1 has a first principal surface 10, and a second principal surface 20. The second principal surface 20 is located on the opposite side from the first principal surface 10. The silicon carbide single crystal substrate 11 forms the second principal surface 20.

The first principal surface 10 is a plane (000-1), or a plane inclined by an off angle of less than 8° with respect to the (000-1) plane, for example. The off angle may be 6° or less, and may be 4° or less. The off angle may be 2° or less. The silicon carbide single crystal substrate 11 and the silicon carbide epitaxial layer 2 are 4H polytype hexagonal crystal silicon carbides, for example. A conductivity type of the silicon carbide single crystal substrate 11 is the n-type, and includes an n-type impurity, such as nitrogen (N) or the like, for example.

The drain electrode 30 is provided on the second principal surface 20. The drain electrode 30 is formed by a material including nickel silicide (NiSi) in the case of the n-type, and including titanium aluminide (TiAl) in the case of the p-type, for example, according to the conductivity type of the silicon carbide single crystal substrate 11. The drain electrode 30 may be formed by a material including titanium aluminide silicon (TiAlSi), for example, regardless of whether the drain electrode 30 is the n-type or the p-type.

The silicon carbide substrate 1 generally includes a drift region 12, a body region 13, a source region 14, and a contact region 18. The drift region 12 includes an n-type impurity, such as nitrogen or the like, for example, and the conductivity type of the drift region 12 is the n-type (first conductivity type). An n-type impurity concentration of the drift region 12 is approximately 7×10¹⁵ cm⁻³, for example. The n-type impurity concentration of the silicon carbide single crystal substrate 11 may be higher than the n-type impurity concentration of the drift region 12. The drift region 12 is an example of a first impurity layer, the body region 13 is an example of a second impurity layer, and the source region 14 is an example of a third impurity layer.

The body region 13 is located on the drift region 12. The body region 13 makes contact with the drift region 12. The body region 13 includes a p-type impurity, such as aluminum (Al) or the like, for example, and the conductivity type of the body region 13 is the p-type (second conductivity type). A channel may be formed in a region of the body region 13 opposing the gate insulator 40.

The source region 14 is located on the body region 13. The source region 14 makes contact with the body region 13. The source region 14 is separated from the drift region 12 by the body region 13. The source region 14 includes an n-type impurity, such as nitrogen, phosphorus (P), or the like, for example, and the conductivity type of the source region 14 is the n-type. The source region 14 forms a portion of the first principal surface 10. The n-type impurity concentration of the source region 14 may be higher than the n-type impurity concentration of the drift region 12.

The contact region 18 makes contact with the body region 13 and the source region 14, for example. The contact region 18 includes a p-type impurity, such as aluminum or the like, for example, and the conductivity type of the contact region 18 is the p-type. A p-type impurity concentration included in the contact region 18 may be higher than the p-type impurity concentration included in the body region 13. The contact region 18 connects the body region 13 and the first principal surface 10. The contact region 18 may form a portion of the first principal surface 10. The n-type impurity concentration or the p-type impurity concentration in each of the impurity regions described above may be measured using Secondary Ion Mass Spectrometry (SIMS), for example.

A gate trench 6 is provided in the first principal surface 10. For example, the first principal surface 10 has a flat portion 5, and the gate trench 6 has an inner surface 6A including a trench sidewall 3 and a bottom surface 4. The gate trench 6 is defined by the trench sidewall 3 and the bottom surface 4. The trench sidewall 3 connects to the flat portion 5. In other words, the inner surface 6A connects to the first principal surface 10. The trench sidewall 3 penetrates the body region 13 and the source region 14, and reaches the drift region 12. The bottom surface 4 connects to the trench sidewall 3. The bottom surface 4 is positioned on the drift region 12.

In a cross sectional view viewed from a direction perpendicular to a longitudinal direction of the gate trench 6, the gate trench 6 has a U-shape, for example. In other words, in the cross sectional view, the trench sidewall 3 is approximately perpendicular with respect to the flat portion 5, and the bottom surface 4 is approximately parallel to the flat portion 5. The source region 14, the body region 13, and the drift region 12 form the trench sidewall 3 of the gate trench 6. The drift region 12 forms the bottom surface 4 of the gate trench 6.

The gate insulator 40 is provided on the inner surface 6A and the first principal surface 10. The gate insulator 40 separates the gate electrode 50 from the silicon carbide substrate 1. The gate insulator 40 is a thermal oxidation film of silicon carbide, for example. The gate insulator 40 is formed by a material including silicon dioxide (SiO₂) and carbon (C), for example. A carbon ratio within the gate insulator 40 is in a range greater than or equal to 10 mass % and less than or equal to 90 mass %, for example. The carbon ratio may be measured by SIMS, for example.

A thickness of the gate insulator 40 is in a range greater than or equal to approximately 20 nm and less than or equal to approximately 80 nm, for example. The gate insulator 40 makes contact with the source region 14, the body region 13, and the drift region 12, at the trench sidewall 3. The gate insulator 40 makes contact with the drift region 12, at the bottom surface 4. The gate insulator 40 may make contact with the source region 14, at the flat portion 5.

The gate electrode 50 is formed of polysilicon including an impurity, such as phosphorus or the like, for example. The impurity, such as phosphorus or the like, is included for adjusting a threshold voltage, for example. The gate electrode 50 has a base portion 51 inside the gate trench 6, and a tapered portion 52 located on the base portion 51. The base portion 51 is a portion, which fills a portion of the gate trench 6, and makes contact with the gate insulator 40 inside the gate trench 6. The base portion 51 opposes the body region 13 via the gate insulator 40 interposed therebetween. The tapered portion 52 is a portion having a width which continuously decreases in a direction further away from the base portion 51. A boundary 56 between the base portion 51 and the tapered portion 52 is located at a position closer to a bottom of the gate trench 6 than an upper end of the gate trench 6. For example, a lower end of the tapered portion 52, that is, a portion of the tapered portion 52 making contact with the gate insulator 40, is located at a position closer to the upper end of the gate trench 6 than an interface between the source region 14 and the body region 13, along a thickness direction of the silicon carbide substrate 1. The lower end of the tapered portion 52 is separated from the interface between the source region 14 and the body region 13, toward the upper end of the gate trench 6 by a distance which is preferably greater than or equal to 80%, and more preferably greater than or equal to 90% of the thickness of the source region 14. If the lower end of the tapered portion 52 is too close to the body region 13, an electric field between the boundary 56 and the body region 13 may surge and cause an insulation breakdown of the gate insulator 40. A side surface 53 of the tapered portion 52 may be a curved surface having a concave shape which curves inward toward the tapered portion 52, for example.

A width WG of an upper end of the tapered portion 52 is smaller than an opening width WT at the upper end of the gate trench 6. The width WG is preferably in a range greater than or equal to 80% and less than or equal to 95%, and more preferably in a range greater than or equal to 90% and less than or equal to 95% of the opening width WT. If the width WG is less than 80% of the opening width WT, the inclination of the side surface 53 becomes too sharp, and the electric field may concentrate near the boundary 56. In addition, a high-precision etching may become required to make the width WG exceed 95% of the opening width WT. The base portion 51 is an example of a first portion, and the tapered portion 52 is an example of a second portion. Along the thickness direction of the silicon carbide substrate 1, a thickness of a portion of the gate electrode 50, located at a position closer to the bottom of the gate trench 6 than the first principal surface 10, is in a range greater than or equal to 60% and less than or equal to 90% of a thickness of the gate electrode 50, for example.

The interlayer insulator 45 is provided in contact with the gate insulator 40. The interlayer insulator 45 is formed of a material including silicon dioxide, for example. The interlayer insulator 45 provides electrical isolation between the gate electrode 50 and the source electrode 16.

The source electrode 16 makes contact with the first principal surface 10. More particularly, the source electrode 16 makes contact with the source region 14 at the first principal surface 10. The source electrode 16 may make contact with the contact region 18. The source electrode 16 is formed of a material including titanium (Ti), aluminum, and silicon (Si), for example. The source electrode 16 makes ohmic contact with the source region 14, for example. The source interconnect 19 makes contact with the source electrode 16. The source interconnect 19 is formed of a material including aluminum, for example.

Next, a manufacturing method of the silicon carbide semiconductor device 100 according to the first embodiment will be described. FIG. 2 through FIG. 7 are cross sectional views illustrating the manufacturing method of the silicon carbide semiconductor device 100 according to the first embodiment.

First, as illustrated in FIG. 2, the silicon carbide substrate 1 is prepared. The silicon carbide single crystal substrate 11 is prepared using sublimation, for example. A maximum diameter of the silicon carbide single crystal substrate 11 is 100 mm or greater, and preferably 150 mm or greater, for example. Next, an epitaxial layer is formed on the silicon carbide single crystal substrate 11. A drift region is epitaxially grown on the silicon carbide single crystal substrate 11 by Chemical Vapor Deposition (CVD) using a gas mixture of silane (SiH₄) and propane (C₃H₈) as a source gas, for example, hydrogen gas (H₂) as a carrier gas, for example, and ammonia (NH₃) as a dopant gas.

Next, ion implantation is performed. Ion implantation of a p-type impurity, such as aluminum or the like, for example, is performed with respect to the surface of the drift region 12. Hence, the body region 13 in contact with the drift region 12 is formed. Next, ion implantation of an n-type impurity, such as phosphorus or the like, for example, is performed with respect to the body region 13. Accordingly, the source region 14, having the conductivity type which is the n-type, is formed. The source region 14 forms the first principal surface 10. The n-type impurity concentration included in the source region 14 is higher than the p-type impurity concentration included in the body region 13. Next, ion implantation of a p-type impurity, such as aluminum or the like, for example, is performed with respect to the source region 14, so as to form the contact region 18.

Next, activation annealing is performed to activate the impurity implanted to the silicon carbide substrate 1 by the ion implantation. A temperature of the activation annealing is preferably in a range higher than or equal to 1500° C. and lower than or equal to 1900° C. An activation annealing time is approximately 30 minutes, for example. An activation annealing environment is preferably an inert gas atmosphere, such as an argon (Ar) atmosphere, for example.

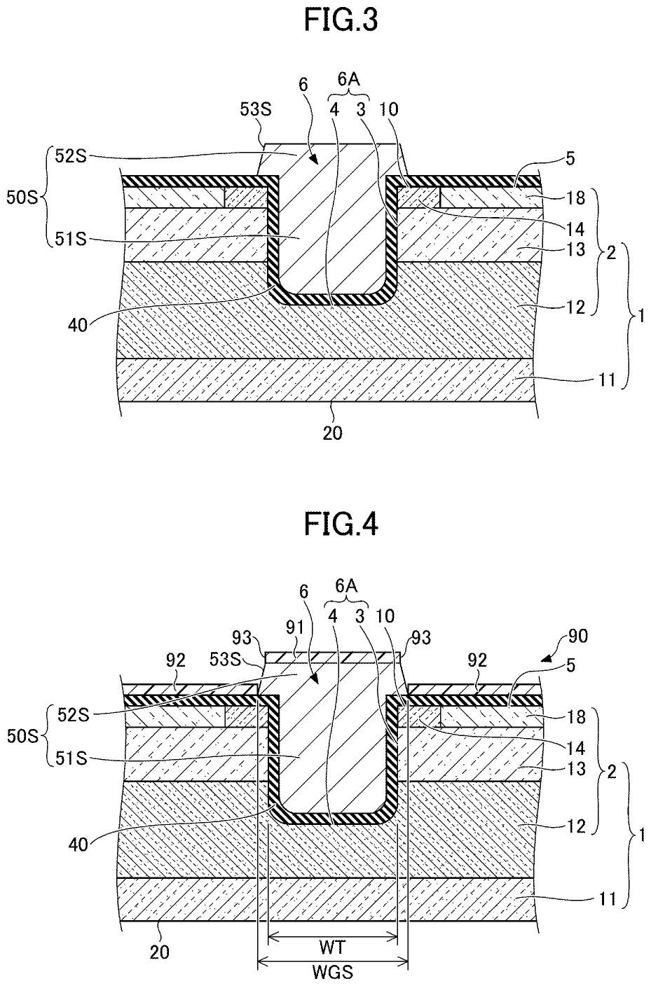

Next, as illustrated in FIG. 3, the gate trench 6 is formed. For example, a mask, having an opening at a position where the gate trench 6 is to be formed, is formed on the first principal surface 10 formed by the source region 14 and the contact region 18. Then, using the mask, a portion of the source region 14, a portion of the body region 13, and a portion of the drift region are removed by etching. The etching may be Reactive Ion Etching (RIE), and particularly Inductively Coupled Plasma Reactive Ion Etching (ICP-RIE), for example. More particularly, the etching may be the Inductively Coupled Plasma Reactive Ion Etching using sulfur hexafluoride (SF₆), or a gas mixture of SF₆ and oxygen (O₂), as a reaction gas. After forming the gate trench 6, the mask is removed.

Next, the gate insulator 40 is formed. For example, the silicon carbide substrate 1 is heated to a temperature in a range higher than or equal to 1300° C. and lower than or equal to 1400° C., for example, in an oxygen-including atmosphere. Hence, the gate insulator 40, which makes contact with the drift region 12 at the bottom surface 4, and makes contact with the drift region 12, the body region 13, and the source region 14 at the trench sidewall 3, is formed. The gate insulator 40, which is formed by thermal oxidation of the silicon carbide substrate 1, includes silicon dioxide and carbon, for example. The gate insulator 40 may be formed by other methods, such as CVD or the like. In the case where the gate insulator 40 is formed by the thermal oxidation, a portion of the silicon carbide substrate 1 becomes included in the gate insulator 40. For this reason, in subsequent processes, the first principal surface 10 and the inner surface 6A are moved slightly to the interface between the gate insulator 40 after the thermal oxidation and the silicon carbide substrate 1. On the other hand, in the case where the gate insulator 40 is formed by deposition, such as the CVD or the like, the positions of the first principal surface 10 and the inner surface 6A do not move because a portion of the silicon carbide substrate 1 does not become included in the gate insulator 40.

After forming the gate insulator 40, a thermal process (NO annealing) may be performed with respect to the silicon carbide substrate 1 in a nitric oxide (NO) gas atmosphere. During the NO annealing, the silicon carbide substrate 1 is held for approximately 1 hour under a condition in a range higher than or equal to 1100° C. and lower than or equal to 1300° C., for example. Hence, nitrogen atoms are introduced to an interface region between the gate insulator 40 and the body region 13. As a result, formation of an interface state at the interface region is reduced, thereby making it possible to improve a channel mobility. Gases (for example, N₂O) other than the NO gas, may be used as the atmospheric gas, as long as the nitrogen atoms can be introduced. Ar annealing using argon (Ar) as the atmospheric gas may further be performed after the NO annealing. A heating temperature of the Ar annealing is higher than or equal to a heating temperature of the NO annealing described above, for example. An Ar annealing time is approximately 1 hour, for example. Accordingly, it is possible to further reduce the formation of the interface state at the interface region between the gate insulator 40 and the body region 13.

Next, a quasi-gate electrode 50S is formed. For example, a polysilicon film is deposited by Low Pressure Chemical Vapor Deposition (LPCVD), for example, and dry etching of the polysilicon layer is thereafter performed. For example, sulfur hexafluoride (SF₆) or the like is used for an etching gas of this dry etching. In addition, the dry etching may be a high-density plasma etching or the like. The quasi-gate electrode 50S has a support portion 51S inside the gate trench 6, and an umbrella portion 52S on the support portion 51S. The umbrella portion 52S hangs over on both sides of the gate trench in an in-plane direction. The in-plane direction refers to an in-plane direction perpendicular to the thickness direction of the silicon carbide substrate 1. A side surface 53S of the umbrella portion 52S is a sloping surface which separates from the support portion 51S along the in-plane direction by a distance which increases toward a downward direction from an upper end of the umbrella portion 52S. A width WGS of a lower end of the umbrella portion 52S is larger than the opening width WT at the upper end of the gate trench 6.

Next, as illustrated in FIG. 4, an etching mask 90 is formed. The etching mask 90 has a first covering portion 91 which covers the umbrella portion 52S, a second covering portion 92 which covers the gate insulator 40 at the sides of the umbrella portion 52S, and an opening 93 which exposes the side surface 53S of the umbrella portion 52S between the first covering portion 91 and the second covering portion 92.

Next, as illustrated in FIG. 5, isotropic etching of the quasi-gate electrode 50S is performed using the etching mask 90. For example, sulfur hexafluoride (SF₆), chlorine (Cl₂), or the like is used for an etching gas of the isotropic etching. In addition, the isotropic etching may be chemical dry etching or the like. Accordingly, the side surface 53S of the quasi-gate electrode 50S is etched to a tapered shape via the opening 93 of the etching mask 90. Then, the gate electrode 50, having the base portion 51 and the tapered portion 52, is formed from the quasi-gate electrode 50S. The side surface 53 of the tapered portion 52 becomes the curved surface having the concave shape which curves inward toward the tapered portion 52, and the width WG at the upper end of the tapered portion 52 becomes smaller than the opening width WT at the upper end of the gate trench 6.

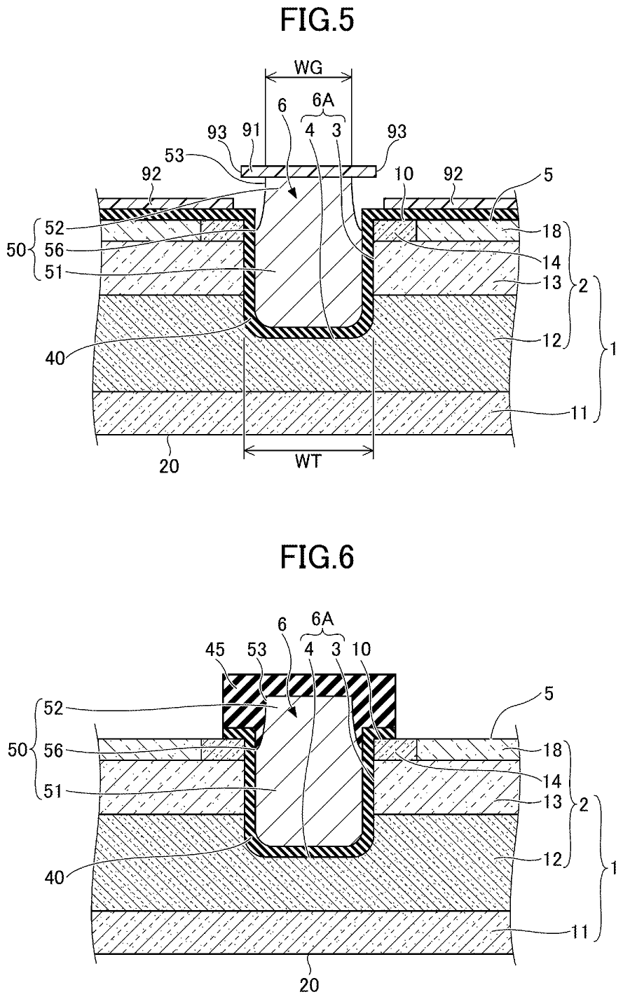

Next, as illustrated in FIG. 6, the etching mask 90 is removed, and the interlayer insulator 45 is formed. For example, the interlayer insulator 45 is formed so as to cover the gate electrode 50, and make contact with the gate insulator 40. The interlayer insulator 45 is formed by CVD, for example. The interlayer insulator 45 is formed of a material including silicon dioxide, for example. Next, portions of the interlayer insulator 45 and the gate insulator 40 are etched, so as to form openings above the source region 14 and the contact region 18. Accordingly, the contact region 18 and the source region 14 are exposed from the gate insulator 40.

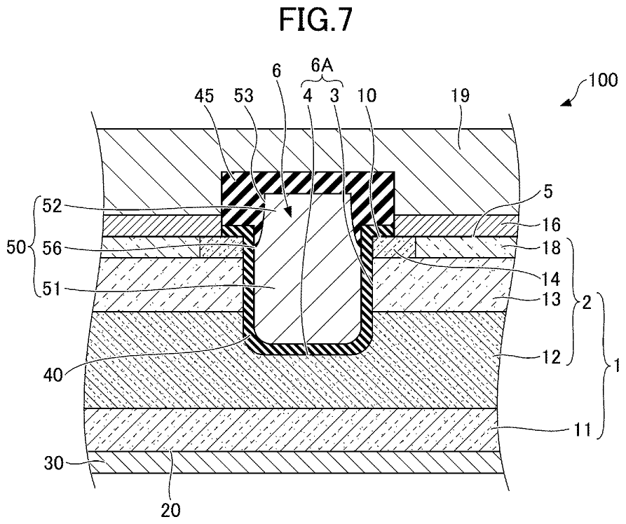

Next, as illustrated in FIG. 7, the source electrode 16 and the source interconnect 19 are formed. More particularly, the source electrode 16, which makes contact with the source region 14 and the contact region 18 at the first principal surface 10, is famed. The source electrode 16 is formed by sputtering, for example. The source electrode 16 is famed of a material including Ti, Al, and Si, for example. Next, alloying annealing is performed. More particularly, the source electrode 16, which makes contact with the source region 14 and the contact region 18, is held for approximately 5 minutes in a temperature range higher than or equal to 900° C. and lower than or equal to 1100° C., for example. Hence, at least a portion of the source electrode 16 reacts with the silicon included in the silicon carbide substrate 1, and becomes silicidized. As a result, the source electrode 16, which makes ohmic contact with the source region 14, is formed. Next, the source interconnect 19, which is electrically connected to the source electrode 16, is formed. The source interconnect 19 is formed on the source electrode 16 and the interlayer insulator 45.

Next, the drain electrode 30 is formed at the second principal surface 20. The drain electrode 30 is formed of a material including NiSi, for example. The material forming the drain electrode 30 is sputtered, for example. Next, laser annealing is performed with respect to the sputtered material. Hence, alloying of the material forming the drain electrode 30 is performed. In place of the alloying by the laser annealing, the alloying may be performed by a thermal process, such as a process including Rapid Thermal Annealing (RTA), for example. A back surface of the silicon carbide substrate 1 may be polished before forming the drain electrode 30.

The silicon carbide semiconductor device 100 according to the first embodiment can be manufactured as described above.

In the silicon carbide semiconductor device 100 according to the first embodiment, the width of the tapered portion 52 continuously decreases as the tapered portion 52 separates more from the base portion 51, and a distance between the gate electrode 50 and a vicinity of a corner portion at the upper end of the gate trench 6 is greater than the thickness of the gate insulator 40. For this reason, it is possible to relax the electric field applied to the gate insulator 40 in the vicinity of the corner portion at the upper end of the gate trench 6. Accordingly, even if the distance between the side surface 53S of the quasi-gate electrode 50S and the upper end of the gate trench 6 becomes smaller than a designed value due to an alignment error of the quasi-gate electrode 50S during the manufacturing process, the silicon carbide semiconductor device 100 having the gate electrode 50 can obtain an excellent withstand voltage.

In addition, according to the manufacturing method described above, even if the alignment error of the quasi-gate electrode 50S occurs, it is possible to easily form the gate electrode 50 having an appropriate width and capable of reducing the concentration of the electric field. Further, the side surface 53 of the tapered portion 52 can easily be formed into the curved surface having the concave shape by the isotropic etching.

The tapered portion 52 may be oxidized, after removing the etching mask 90 and before forming the interlayer insulator 45. By oxidizing the tapered portion 52, the change in the inclination becomes gradual at the boundary 56 between the base portion 51 and the tapered portion 52, thereby further reducing the concentration of the electric field. In this oxidation process, the tapered portion 52 is heated to a temperature in a range higher than or equal to 850° C. and lower than or equal to 950° C. in an oxygen-including atmosphere, for example. In addition, an oxygen ratio in the atmosphere is in a range greater than or equal to 10 volume % and less than or equal to 100 volume %, and preferably in a range greater than or equal to 80 volume % and less than or equal to 90 volume %, for example.

### Modification of First Embodiment

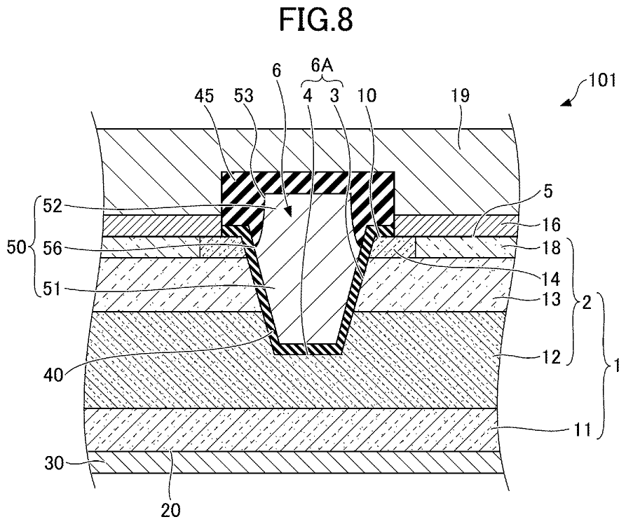

Next, a modification of the first embodiment will be described. A cross sectional shape of the gate trench of this modification differs from that of the first embodiment. FIG. 8 is a cross sectional view illustrating the structure of the silicon carbide semiconductor device according to the modification of the first embodiment.

While the gate trench 6 is U-shaped in the cross sectional view of the silicon carbide semiconductor device 100 according to the first embodiment, the gate trench 6 is V-shaped in the cross sectional view of a silicon carbide semiconductor device 101 according to the modification. In other words, in the silicon carbide semiconductor device 101, the trench sidewall 3 is inclined so that the width of the gate trench 6 decreases in a tapered shape toward the bottom surface 4 in the cross sectional view. The trench sidewall 3 is inclined in a range greater than or equal to 52° and less than or equal to 72° with respect to the (000-1) plane. The trench sidewall 3 includes the (0-33-8) plane, for example. The bottom surface 4 is approximately parallel to the flat portion 5.

Otherwise, the structure of the modification is similar to that of the first embodiment.

The silicon carbide semiconductor device 101 according to the modification can obtain effects similar to those obtainable by the silicon carbide semiconductor device 100. Further, because the trench sidewall 3 is inclined with respect to the (000-1) within an appropriate range, excellent mobility is obtained at the trench sidewall 3, and a channel resistance can be reduced.

Although the embodiments are described above in detail, the present disclosure is not limited to specific embodiments, and various variations and modifications may be made without departing from the scope of the appended claims.

### DESCRIPTION OF REFERENCE NUMERALS

1 Silicon carbide substrate
2 Silicon carbide epitaxial layer
3 Trench sidewall
4 Bottom surface
5 Flat portion
6 Gate trench
6A Inner surface
10 First principal surface
11 Silicon carbide single crystal substrate
12 Drift region
13 Body region
14 Source region
16 Source electrode
18 Contact region
19 Source interconnect
20 Second principal surface
30 Drain electrode
40 Gate insulator
45 Interlayer insulator
50 Gate electrode
50S Quasi-gate electrode
51 Base portion
51S Support portion
52 Tapered portion
52S Umbrella portion
53 Side surface
53S Side surface
56 Boundary
90 Etching mask
91 First covering portion
92 Second covering portion
93 Opening
100, 101 Silicon carbide semiconductor device

1. A silicon carbide semiconductor device comprising:
a silicon carbide substrate having a first principal surface provided with a gate trench, and a second principal surface located on an opposite side from the first principal surface, the gate trench having an inner surface connecting to the first principal surface;
a gate insulator provided on the inner surface of the gate trench; and
a gate electrode provided on the gate insulator,
wherein the gate electrode includes
a base portion in contact with the gate insulator, and filling a portion of the gate trench, and
a tapered portion provided on the base portion, having a width which continuously decreases in a direction further away from the base portion, in a cross sectional view viewed from a direction perpendicular to a longitudinal direction of the gate trench, and
wherein a boundary between the base portion and the tapered portion is located at a position closer to a bottom of the gate trench than an upper end of the gate trench.

2. The silicon carbide semiconductor device as claimed in claim 1, wherein a side surface of the tapered portion is a curved surface having a concave shape which curves inward toward the tapered portion.

3. The silicon carbide semiconductor device as claimed in claim 1, wherein a width of an upper end of the tapered portion is in a range greater than or equal to 80% and less than or equal to 95% of an opening width at the upper end of the gate trench.

4. The silicon carbide semiconductor device as claimed in claim 1, wherein the silicon carbide substrate includes
a first impurity layer having a first conductivity type,
a second impurity layer, provided on a surface of the first impurity layer closer to the first principal surface, and having a second conductivity type different from the first conductivity type, and
a third impurity layer, provided on a surface of the second impurity layer closer to the first principal surface so as to be separated from the first impurity layer, and having the first conductivity type, and
the inner surface of the gate trench reaches the first impurity layer by penetrating the third impurity layer and the second impurity layer.

5. The silicon carbide semiconductor device as claimed in claim 4, wherein a lower end of the tapered portion is separated from an interface between the second impurity layer and the third impurity layer toward the upper end of the gate trench by a distance which is greater than or equal to 80% of a thickness of the third impurity layer.

6. The silicon carbide semiconductor device as claimed in claim 4, wherein the base portion opposes the second impurity layer via the gate insulator interposed therebetween.

7. The silicon carbide semiconductor device as claimed in claim 1, wherein the gate trench includes a trench sidewall having a (0-33-8) plane.

8. A silicon carbide semiconductor device comprising:
a silicon carbide substrate having a first principal surface provided with a gate trench, and a second principal surface located on an opposite side from the first principal surface,
wherein the silicon carbide substrate includes
a first impurity layer having a first conductivity type,
a second impurity layer, provided on a surface of the first impurity layer closer to the first principal surface, and having a second conductivity type different from the first conductivity type, and
a third impurity layer, provided on a surface of the second impurity layer closer to the first principal surface so as to be separated from the first impurity layer, and having the first conductivity type,
wherein the gate trench has an inner surface, connecting to the first principal surface, and reaching the first impurity layer by penetrating the third impurity layer and the second impurity layer;
a gate insulator provided on the inner surface of the gate trench; and
a gate electrode provided on the gate insulator,
wherein the gate electrode includes
a base portion in contact with the gate insulator, filling a portion of the gate trench, and opposing the second impurity layer via the gate insulator interposed therebetween, and
a tapered portion provided on the base portion, having a width which continuously decreases in a direction further away from the base portion, in a cross sectional view viewed from a direction perpendicular to a longitudinal direction of the gate trench,
wherein a boundary between the base portion and the tapered portion is located at a position closer to a bottom of the gate trench than an upper end of the gate trench, and
wherein a side surface of the tapered portion is a curved surface having a concave shape which curves inward toward the tapered portion.

9. A manufacturing method of a silicon carbide semiconductor device, comprising:
preparing a silicon carbide substrate having a principal surface;
forming, in the principal surface, a gate trench having an inner surface connecting to the principal surface;
forming a gate insulator on the inner surface of the gate trench;
forming a quasi-gate electrode on the gate insulator, filling a portion of the gate trench, and extending upward from an upper end of the gate trench; and
forming a gate electrode by etching the quasi-gate electrode,
wherein the gate electrode after the etching includes
a base portion in contact with the gate insulator, and filling a portion of the gate trench, and
a tapered portion provided on the base portion, having a width which continuously decreases in a direction further away from the base portion, in a cross sectional view viewed from a direction perpendicular to a longitudinal direction of the gate trench.

10. The manufacturing method of the silicon carbide semiconductor device as claimed in claim 9, wherein the forming the gate trench forms the gate trench including a trench sidewall having a (0-33-8) plane.

11. The manufacturing method of the silicon carbide semiconductor device as claimed in claim 9, wherein the first principal surface is a plane (000-1), or a plane inclined by an off angle of less than 8° with respect to the (000-1) plane, and the off angle is 6° or less.

12. The silicon carbide semiconductor device as claimed in claim 8, wherein the gate trench includes a trench sidewall having a (0-33-8) plane.

13. The silicon carbide semiconductor device as claimed in claim 8, wherein the first principal surface is a plane (000-1), or a plane inclined by an off angle of less than 8° with respect to the (000-1) plane, and the off angle is 6° or less.

14. The silicon carbide semiconductor device as claimed in claim 1, wherein the first principal surface is a plane (000-1), or a plane inclined by an off angle of less than 8° with respect to the (000-1) plane, and the off angle is 6° or less.
